(19) United States
(12) Patent Application Publication
(10) Pub. No.: US 2013/0186524 A1
(43) Pub. Date: Jul. 25, 2013

(54) Al PLATING LAYER/Al-Mg PLATING LAYER MULTI-LAYERED STRUCTURE ALLOY PLATED STEEL SHEET HAVING EXCELLENT PLATING ADHESIVENESS AND CORROSION RESISTANCE, AND METHOD OF MANUFACTURING THE SAME

(71) Applicants: Young-Jin Kwak, Gwangyang-si (KR); Dong-Yoeul Lee, Gwangyang-si (KR); Yong-Hwa Jung, Gwangyang-si (KR); Woo-Sung Jung, Gwangyang-si (KR); Mun-Jong Eom, Gwangyang-si (KR); Kyoung-Bo Kim, Gwangyang-si (KR); Kyung-Hoon Nam, Gwangyang-si (KR); Tae-Yeob Kim, Gwangyang-si (KR); Sang-Cheol Lee, Gwangyang-si (KR); Sang-Hoon Park, Gwangyang-si (KR)

(72) Inventors: Young-Jin Kwak, Gwangyang-si (KR); Dong-Yoeul Lee, Gwangyang-si (KR); Yong-Hwa Jung, Gwangyang-si (KR); Woo-Sung Jung, Gwangyang-si (KR); Mun-Jong Eom, Gwangyang-si (KR); Kyoung-Bo Kim, Gwangyang-si (KR); Kyung-Hoon Nam, Gwangyang-si (KR); Tae-Yeob Kim, Gwangyang-si (KR); Sang-Cheol Lee, Gwangyang-si (KR); Sang-Hoon Park, Gwangyang-si (KR)

(73) Assignee: POSCO, Pohang-si (KR)

(21) Appl. No.: 13/824,421

(22) PCT Filed: Dec. 20, 2011
(86) PCT No.: PCT/KR11/09854

§ 371 Date: Mar. 18, 2013

(30) Foreign Application Priority Data
Dec. 28, 2010 (KR) 10-2010-0137246

(51) Int. Cl. C23C 14/58; B32B 15/01

(52) U.S. Cl. CPC C23C 14/5806; B32B 15/012
USPC 148/531; 148/320

(57) ABSTRACT

Provided is an aluminum (Al) plating layer/aluminum (Al)-magnesium (Mg) plating layer multi-layered structure alloy plated steel sheet having excellent plating adhesiveness and corrosion resistance, which is characterized in that the Al—Mg plating layer is formed on the Al plating layer. According to the present invention, corrosion resistance of an Al plated steel sheet is further improved by forming an Al—Mg alloy plating layer, and plating adhesiveness between plating layer and underlying steel sheet may be improved as well as excellent stability and practicality being realized.

### TECHNICAL FIELD

The present invention relates to an aluminum (Al) plating layer/aluminum(Al)-magnesium(Mg) plating layer multi-layered structure alloy plated steel sheet having excellent plating adhesiveness and corrosion resistance, and a method of manufacturing the same, and more particularly, to an Al plating layer/Al—Mg plating layer multi-layered structure alloy plated steel sheet having excellent plating adhesiveness and corrosion resistance, in which excellent corrosion resistance is secured by forming an Al—Mg alloy plating layer on an Al plating layer as well as improving adhesiveness between the plating layer and an underlying steel sheet, and a method of manufacturing the same.

### BACKGROUND ART

Aluminum (Al) plated steel sheets have been widely used in household kitchen utensils, automotive components, thermal devices, construction materials, and heat resistant materials, as Al plated steel sheets have fine surfaces and excellent corrosion and heat resistance in comparison to zinc (Zn) plated steel sheets. Al plated steel sheets protect underlying iron from corrosion by a sacrificial protective action, in which aluminum, having a higher oxidation potential dissolves earlier than the underlying iron, and a corrosion inhibitory action, in which corrosion is delayed by a formation of a fine oxide layer.

However, since corrosive environments have continuously been severe and assurance of a higher level of corrosion resistance has been required in terms of resource and energy conservation, Al—Mg alloy plated steel sheets, in which corrosion resistance is further improved by adding magnesium (Mg) to an Al plating layer, have emerged, instead of general Al plated steel sheets.

When a technique of manufacturing a typical Al—Mg alloy plated steel sheet is examined, a method of hot dip plating by adding Mg to an Al plating bath has generally been used. However, when a Mg-added molten metal bath is exposed to air, a large amount of dross may be generated due to an oxidation reaction of a Mg element, and ignition may occur in some cases. The foregoing phenomena may make a plating operation difficult or impossible, and since fumes generated from Mg are very toxic to the human body and may cause air pollution and safety problems for steelworkers, the use thereof may be extremely limited.

Accordingly, techniques of manufacturing an Al—Mg plating layer by using a vacuum deposition method (thermal evaporation, electron beam induced deposition, sputtering, ion plating, electromagnetic levitation physical vapor deposition, etc.) have been developed in order to resolve limitations generated by the foregoing hot dip plating method. Korean Patent No. 010644 and Korean Patent Application Laid-Open Publication No. 2004-0112387 were disclosed as typical related art for manufacturing an Al—Mg plating layer by using a vacuum deposition method. First, Korean Patent No. 010644 provides a method of forming an Al—Mg plating layer on a steel sheet by using a vacuum deposition method, in which Al and Mg are respectively evaporated by using two evaporation sources.

However, control of an alloy composition in the plating layer may be difficult because control of an Mg evaporation rate may be difficult. Control of plating weight may not only be difficult because two evaporation sources are used at the same time, but the plating layer may also be easily detached during processing because the Al—Mg alloy plating layer may have inferior plating adhesiveness with respect to underlying iron in comparison to an Al plating layer.

Also, Korean Patent Application Laid-Open Publication No. 2004-0112387 provides a method of forming an Al—Mg plating layer, in which a surface of an Al substrate is heated in a temperature range of 350° C. to 500° C. in a vacuum chamber, and Mg is then evaporated from an evaporation source having a temperature of 600° C. or more to be deposited on the Al-plated substrate and is simultaneously alloyed therewith.

However, in a continuous strip vacuum plating process, there may be limitations in applying the foregoing method to an actual line, because temperature of heating the strip for alloying may be so high that a surface of a vacuum rubber roll, which maintains a degree of vacuum in a vacuum chamber by shielding the vacuum chamber from the air through contact with the strip, may be damaged.

Therefore, demands for Al—Mg alloy plated steel sheets having excellent stability, practicality, and plating adhesiveness as well as excellent corrosion resistance are rapidly increasing.

### DISCLOSURE

### Technical Problem

An aspect of the present invention provides an Al—Mg alloy plated steel sheet having excellent stability, practicality, and improved plating adhesiveness between a plating layer and an underlying steel sheet, and a method of manufacturing the same, when an Al—Mg alloy plated steel sheet is provided in order to improve corrosion resistance of an Al plated steel sheet.

### Technical Solution

According to an aspect of the present invention, there is provided an aluminum (Al) plating layer/aluminum (Al)-magnesium (Mg) plating layer multi-layered structure alloy plated steel sheet having excellent plating adhesiveness and corrosion resistance comprising: an underlying steel sheet; an Al plating layer including about 85 wt % or more of Al formed on the underlying steel sheet; and an Al—Mg plating layer formed on the Al plating layer.

The Al—Mg plating layer may include about 20 wt % to about 80 wt % of Mg, residual Al and other unavoidable impurities.

A thickness of the Al plating layer may be within a range of about 3.5 μm to about 15 μm.

A thickness of the Al—Mg plating layer, for example, may be within a range of about 1 μm to about 5 μm.

According to another aspect of the present invention, there is provided a method of manufacturing an Al plating layer/Al—Mg plating layer multi-layered structure alloy plated steel sheet having excellent plating adhesiveness and corrosion resistance comprising: plating an underlying steel sheet with Al to form an Al plating layer having about 85 wt % or more of Al; vacuum depositing Mg on the Al plating layer to form a Mg deposition layer; and performing an alloying heat treatment on a steel sheet including the Al plating layer and the Mg deposition layer in a temperature range of about 350° C. to abut 450° C. for about 3 seconds to about 100 seconds to form an Al—Mg plating layer on the Al plating layer.

The forming of the Al plating layer may be performed such that the Al plating layer has a thickness within a range of about 3.5 μm to about 15 μm.

The forming of the Mg deposition layer may be performed by vacuum depositing Mg at a degree of vacuum range of about 10⁻² mbar to about 10⁻⁵ mbar.

The forming of the Mg deposition layer, for example, may be performed such that the Mg deposition layer has a thickness within a range of about 0.3 μm to about 2.0 μm.

### Advantageous Effects

According to an aspect of the present invention, corrosion resistance may be further improved because an external surface of a steel sheet is formed of an Al—Mg plating layer, plating adhesiveness may also be excellently secured because an interface between the plating layer and an underlying steel sheet is formed of an Al plating layer, and excellent stability and practicality may be obtained.

### DESCRIPTION OF DRAWINGS

The above and other aspects, features and other advantages of the present invention will be more clearly understood from the following detailed description taken in conjunction with the accompanying drawings, in which:

FIG. 1 is a schematic view illustrating an example of a manufacturing process of an Al—Mg alloy plated steel sheet according to the present invention;

FIG. 2 is a scanning electron microscope (SEM) micrograph showing a cross-sectional example of an Al—Mg alloy plated steel sheet according to the present invention;

FIG. 3 is a graph obtained by glow discharge spectrometry (GDS) showing a distribution of components according to a thickness of a plating layer of an Al—Mg alloy plated steel sheet according to the present invention;

FIG. 4 is photographs taken after corrosion experiments performed on (a) a general Al plated steel sheet, and (b) and (c), Al—Mg alloy plated steel sheets according to the present invention;

FIG. 5 is photographs showing surfaces of (a) a general Al plated steel sheet and (b) an Al—Mg alloy plated steel sheet according to the present invention, after mini bumpers are manufactured by hot press forming thereof; and

FIG. 6 shows (a), a schematic diagram of a mini bumper manufactured by using an Al—Mg alloy plated steel sheet according to the present invention, in which portions to be subjected to SEM observations are marked, (b), a SEM micrograph of the portion marked by ‘1’ in (a), (c), a SEM micrograph of the portion marked by ‘2’ in (a), and (d), micrographs of a cross section of the mini bumper obtained by electron probe microanalysis (EPMA) mapping analysis.

### BEST MODE

Although aluminum (Al) plated steel sheets have been widely used due to excellent corrosion resistance, Al—Mg alloy plated steel sheets including magnesium (Mg) have recently received attention for use in severely corrosive environments. However, with respect to an Al—Mg plating layer, the plating layer may be easily detached during processing because plating adhesiveness thereof may be inferior to that of an Al plating layer. That is, although Al—Mg plated steel sheets have better corrosion resistance, there may be limitations in the practicality thereof due to poor adhesiveness.

Thus, in order to resolve the foregoing limitations, the present inventors developed a plated steel sheet in which plating adhesiveness is excellently secured by forming an Al plating layer on an underlying steel sheet through a method of an alloying heat treatment after a vacuum deposition of Mg on an Al plated steel sheet, and simultaneously, corrosion resistance is further improved by forming an Al—Mg plating layer on the Al plating layer.

Hereinafter, a steel sheet of the present invention is described in detail.

An aspect of the present invention provides an Al plating layer/Al—Mg plating layer multi-layered structure alloy plated steel sheet having excellent plating adhesiveness and corrosion resistance comprising: an underlying steel sheet; an Al plating layer including 85 wt % or more of Al formed on the underlying steel sheet; and an Al—Mg plating layer formed on the Al plating layer.

A typical Al—Mg alloy plated steel sheet has excellent corrosion resistance by directly forming an Al—Mg alloy plating layer on an underlying steel sheet, but adhesiveness of the Al—Mg plating layer with respect to an underlying iron (Fe) may be lower than that of an Al plating layer. Therefore, the present inventors first position an Al plating layer instead of an Al—Mg plating layer at a portion in contact with an underlying iron.

Also, Mg is added on the Al plating layer to form an Al—Mg plating layer having better corrosion resistance than that of the Al plating layer and therefore, superior corrosion resistance may be secured. That is, both plating adhesiveness and corrosion resistance may be secured by positioning the Al plating layer at a lower portion of a total plating layer in contact with the underlying iron and the Al—Mg plating layer at an upper portion thereof.

In addition, since sufficient corrosion resistance may be secured even in the case of a low plating weight due to the addition of Mg, a thickness of the plating layer may be decreased in comparison to that of a typical Al plated steel sheet. As a result, a generation of cracks in the plating layer may be reduced by increasing thickness shares of Fe₃Al and FeAl intermetallic compound layers having a relatively low degree of embrittlement, while decreasing a thickness of a Fe₂Al₅ intermetallic compound layer affecting cracks in the plating layer during a process such as a hot press forming heat treatment. Therefore, pitting corrosion resistance of hot press formed components may be particularly improved.

At this time, the Al plating layer may include 85 wt % or more of Al. An Al plated steel sheet used for manufacturing the Al—Mg alloy plated steel sheet may be manufactured through a method such as hot dip plating or vacuum deposition. For example, a plated steel sheet including at least 85 wt % or more of Al may be used in order to form an Al—Mg plating layer having high corrosion resistance.

At this time, the Al—Mg plating layer may include 20 wt % to 80 wt % of Mg, residual Al, and other unavoidable impurities. Corrosion resistance, for example, may be secured when Al exists in a state of Al—Mg alloy instead of existing alone. When a content of Mg is less than 20 wt % or greater than 80 wt %, such that a content of Al becomes too small, there may be limitations in securing corrosion resistance because portions in the Al—Mg plating layer, in which Al and Mg exist in an alloy state, are insufficient.

Also, a thickness of the Al plating layer may be within a range of 3.5 μm to 15 μm. When the thickness of the Al plating layer is less than 3.5 μm, adhesiveness between the plating layer and the underlying steel sheet may be insufficiently secured, and when the thickness of the Al plating layer is greater than 15 μm, a thickness of the Al—Mg plating layer may be excessively high because an amount of Al alloyed with Mg becomes too large during an alloying heat treatment.

Further, the thickness of the Al—Mg plating layer, for example, may be within a range of 1 μm to 5 μm. When the thickness of the plating layer is less than 1 μm, sufficient improvement of corrosion resistance may not be anticipated because the plating layer is too thin and a content of Mg is also relatively small. On the other hand, when the thickness of the plating layer is greater than 5 μm, the plating layer may be vulnerable to pitting corrosion because generation of cracks is facilitated during processing due to the excessively thick plating layer and it is also not desirable in terms of manufacturing costs. Therefore, the thickness of the Al—Mg plating layer may be controlled to be within a range of 1 μm to 5 μm.

Hereinafter, a method of manufacturing a steel sheet of the present invention is described in detail.

Another aspect of the present invention provides a method of manufacturing an Al—Mg alloy plated steel sheet having excellent plating adhesiveness and corrosion resistance comprising: plating an underlying steel sheet with Al to form an plating layer having 85 wt % or more of Al; vacuum depositing Mg on the Al plating layer to form a Mg deposition layer; and performing an alloying heat treatment on a steel sheet including the Al plating layer and the Mg deposition layer in a temperature range of 350° C. to 450° C. for 3 seconds to 100 seconds to form an Al—Mg plating layer on the Al plating layer.

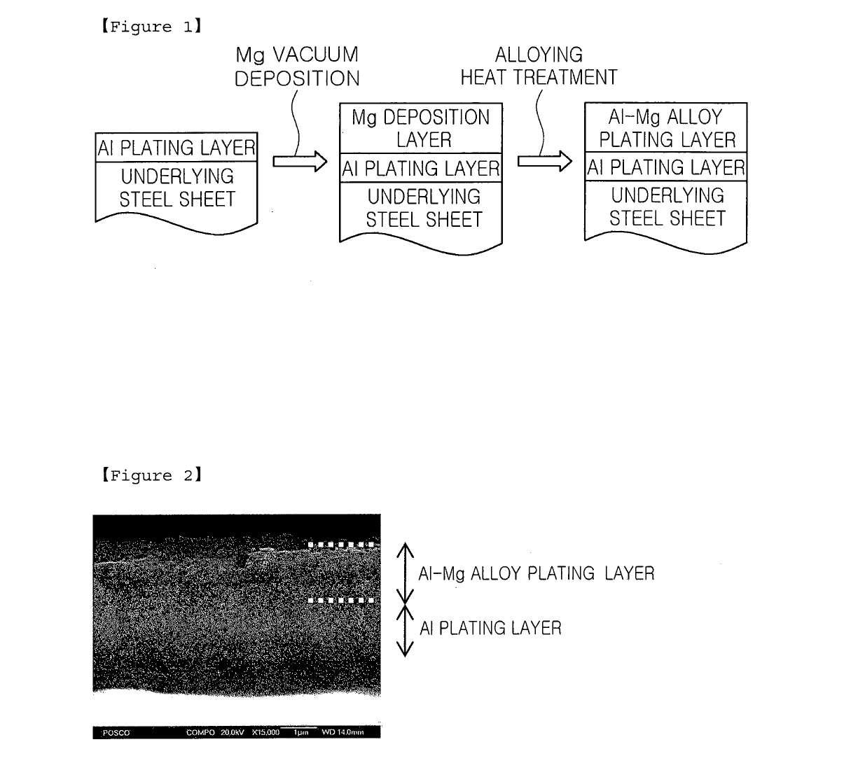

Hereinafter, the manufacturing method is described according to FIG. 1, but this merely suggests an example for more complete understanding of the present invention and the scope of the present invention is not limited to the following drawings. First, Al plating is performed on an underlying steel sheet to form an Al plating layer and Mg is vacuum deposited on the formed Al plating layer to form a Mg deposition layer. Thereafter, Al in the Al plating layer is alloyed into the Mg deposition layer by performing an alloying heat treatment. Finally, a structure is formed in which an Al—Mg alloy layer is formed at an upper portion of a total plating layer and an Al plating layer exists at a lower portion thereof.

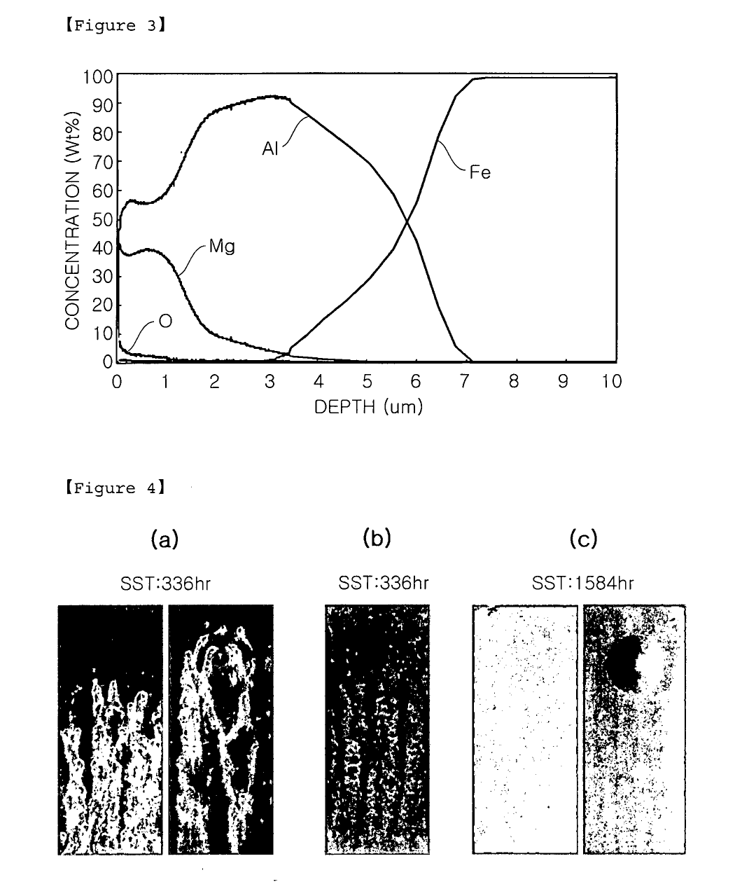

FIG. 2 shows a scanning electron microscope (SEM) micrograph of a cross section of an Al—Mg alloy plated steel sheet manufactured according to the foregoing method and it may be understood that an Al plating layer is formed at a lower portion of a total plating layer and an Al—Mg alloy layer is formed at an upper portion thereof. According to glow discharge spectrometry (GDS) analysis of FIG. 3, it, may be understood that an underlying steel sheet mostly composed of Fe is continuously positioned from a deepest point from a surface of the steel sheet, an Al plating layer exists because an Al component is distributed thereon, and a layer alloyed with Al and Mg exists because a Mg component on the Al plating layer is also gradually increased.

At this time, the plating of Al may be performed such that 85 wt % or more of Al exists in the Al plating layer in order to secure high corrosion resistance, and the forming of the Al plating layer may be performed such that the Al plating layer has a thickness within a range of 3.5 μm to 15 μm in order to secure adhesiveness with respect to the underlying steel sheet and control of the thickness of the Al—Mg alloy layer.

Next, the Al plated steel sheet is plated with Mg, and at this time, a typical vacuum deposition method, e.g., an electron beam method, a sputtering method, a thermal evaporation method, an induction heating evaporation method, or an ion plating method, may be used for plating Mg. For example, in order to improve productivity, it may be effective to use an electromagnetic levitation induction heating method capable of high-rate deposition.

At this time, the forming of the Mg deposition layer may be performed by vacuum depositing Mg at a degree of vacuum range of 10⁻² mbar to 10⁻⁵ mbar. When the degree of vacuum is greater than 10⁻² mbar, it may cause adverse effects on high deposition rate and uniform plating, because risk of generation of arcing during electromagnetic levitation-physical vapor deposition (EML-PVD) plating may be high and choking may not facilitated due to a small pressure difference with respect to the inside of a vapor distribution box. When the degree of vacuum is less than 10⁻⁵ mbar, it may not be desirable in terms of maintenance of an initial degree of vacuum.

Also, the forming of the Mg deposition layer may be performed such that the Mg deposition layer has a thickness within a range of 0.3 μm to 2.0 μm. This may affect on a thickness of the Al—Mg plating layer after an alloying heat treatment. When the thickness of the Mg deposition layer is less than 0.3 μm, sufficient corrosion resistance may not be secured because the formed Al—Mg plating layer is thin, and when the thickness of the Mg deposition layer is greater than 2.0 μm, cracks may easily occur because the plating layer is too thick.

Further, the forming of the Al—Mg plating layer may be performed by an alloying heat treatment in a temperature range of 350° C. to 450° C. for 3 seconds to 100 seconds. The alloying heat treatment may be performed in an air or gas (nitrogen, inert gas, or mixture thereof) environment by using an induction heating or infrared heating method.

When the alloying heat treatment temperature is less than 350° C. or the alloying heat treatment time is less than 3 seconds, the Al—Mg plating layer may not be properly formed because diffusion between the Al plating layer and the Mg deposition layer may not be sufficiently performed. When the alloying heat treatment temperature is greater than 450° C. or the alloying heat treatment time is greater than 100 seconds, a phenomenon of detachment of the plating layer during processing may be generated because adhesiveness deteriorates due to the generation of a Fe₂Al₅ alloy phase having a high degree of embrittlement caused by excessive alloying of Fe and Al, and an alloy plated steel sheet having an Al—Mg mono layer may be formed instead of an Al/Al—Mg multi-layered structure being formed, due to excessive alloying. Therefore, the alloying heat treatment may be performed within the foregoing ranges, and the thickness of the Al—Mg plating layer may be controlled by properly adjusting temperature and time within the foregoing ranges.

As described above, the present invention provides the Al—Mg alloy plated steel sheet and the method of manufacturing the same. Therefore, the present invention may secure excellent plating adhesiveness by forming the Al plating layer on the underlying steel sheet through the alloying heat treatment after the vacuum deposition of Mg on the Al plated steel sheet, and simultaneously, corrosion resistance may be further improved by forming the Al—Mg plating layer on the Al plating layer.

Hereinafter, the present invention will be described in more detail, according to examples. However, the following examples are merely provided to allow for a more complete description of the present invention, and the scope of the present invention is not limited thereto.

### Example

Mg platings were performed with conditions presented in Table 1 on a hot dip Al—Si plated steel sheet, in which an underlying steel sheet was plated with Al at a plating weight of 40 g/m², by using an electromagnetic levitation induction heating deposition method as one of vacuum deposition methods in a vacuum chamber at a pressure range of 10⁻² mbar to 10⁻⁵ mbar. Thereafter, alloying heat treatments were performed with conditions presented in Table 1 on the Al plated steel sheets having the Mg plating layer by using an induction heating method, and Al—Mg alloy plated steel sheets were manufactured, in which an Al plating layer was formed at a lower portion of a total plating layer and an Al—Mg plating layer was formed at an upper portion thereof. Alloying heat treatment times were all controlled to be within 3 seconds to 100 seconds.

Experiments for evaluating plating adhesiveness and corrosion resistance of the manufactured Al—Mg alloy plated steel sheets were performed and the results thereof are presented in Table 1. First, plating adhesiveness was evaluated by optically comparing a state of delamination, after a sample having a size of 50 mm×100 mm was bent at an angle of 60° and a scotch tape was then adhered to a bent portion and peeled off. Corrosion resistance was evaluated based on ASTM B-117 by measuring a length of time until 5% of rust occurs after introducing a sample having a size of 75 mm×150 mm into a salt spray tester and the result thereof was evaluated by comparing with a general hot dip Al plated steel sheet.

TABLE 1

| | | | | Alloying | | |
|---|---|---|---|---|---|---|
| | | Mg | | heat | | |
| | | plating | Forma- | treat- | | |
| | Al | layer | tion of | ment | | Corro- |
| | plating | thick- | Al—Mg | temper- | | sion |
| | weight | ness | alloy | ature | Plating | resis- |
| Category | (g/m²) | (μm) | layer | (° C.) | adhesiveness | tance |
| Inventive | 40 | 0.3 | Yes | 350 | No | 1500 |
| Example 1 | | | | | delamination | |
| Inventive | 40 | 0.5 | Yes | 400 | No | 1700 |
| Example 2 | | | | | delamination | |
| Inventive | 40 | 0.5 | Yes | 450 | No | 1200 |
| Example 3 | | | | | delamination | |
| Inventive | 40 | 1.0 | Yes | 350 | No | 1300 |
| Example 4 | | | | | delamination | |
| Inventive | 40 | 1.0 | Yes | 400 | No | 1400 |
| Example 5 | | | | | delamination | |
| Inventive | 40 | 1.0 | Yes | 450 | No | 1450 |
| Example 6 | | | | | delamination | |
| Inventive | 40 | 2.0 | Yes | 350 | No | 1700 |
| Example 7 | | | | | delamination | |
| Inventive | 40 | 2.0 | Yes | 400 | No | 1750 |
| Example 8 | | | | | delamination | |
| Inventive | 40 | 1.5 | Yes | 450 | No | 1650 |
| Example 9 | | | | | delamination | |
| Inventive | 20 | 2.0 | Yes | 380 | No | 980 |
| Example 10 | | | | | delamination | |
| Inventive | 20 | 1.0 | Yes | 450 | No | 950 |
| Example 11 | | | | | delamination | |
| Inventive | 20 | 0.3 | Yes | 350 | No | 900 |
| Example 12 | | | | | delamination | |
| Inventive | 10 | 0.5 | Yes | 440 | No | 700 |
| Example 13 | | | | | delamination | |
| Inventive | 10 | 1.0 | Yes | 355 | No | 750 |
| Example 14 | | | | | delamination | |
| Inventive | 10 | 2.0 | Yes | 400 | No | 800 |
| Example 15 | | | | | delamination | |
| Comparative | 40 | — | — | — | No | 220 |
| Example 1 | | | | | delamination | |
| Comparative | 80 | — | — | — | No | 300 |
| Example 2 | | | | | delamination | |
| Comparative | 40 | 0.5 | No | 300 | No | 250 |
| Example 3 | | | | | delamination | |
| Comparative | 40 | 0.5 | No | 340 | No | 250 |
| Example 4 | | | | | delamination | |
| Comparative | 40 | 0.5 | Yes | 470 | Partial | 700 |
| Example 5 | | | | | delamination | |
| Comparative | 40 | 2.3 | Yes | 350 | Partial | 1000 |
| Example 6 | | | | | delamination | |

With respect to Inventive Examples 1 to 15, it may be understood that both plating adhesiveness and corrosion resistance were excellently secured, because delaminations were not generated in the experiments of evaluating plating adhesiveness and it took long time until the generation of rust in the experiments of evaluating corrosion resistance due to the fact that thicknesses of Mg plating layers and alloying heat treatment temperatures were in accordance with the conditions of the present invention.

On the other hand, with respect to Comparative Examples 1 and 2, excellent plating adhesiveness was obtained because typical Al plated steel sheets were used, in which Mg platings were not performed. However, it may be confirmed that times until the generation of rust were short because corrosion resistances were relatively poor in comparison to those of the Al—Mg alloy plated steel sheets.

Also, with respect to Comparative Examples 3 and 4, Mg platings were performed according to the conditions of the present invention, but alloying between Al and Mg was insufficiently performed due to very low alloying heat treatment temperatures and thus, there were limitations in improving corrosion resistance because times until the generation of rust were short.

Further, with respect to Comparative Example 5, Mg plating was performed according to the conditions of the present invention, and corrosion resistance may be secured because alloying between Al and Mg excessively occurred due to excessively high alloying heat treatment temperature. However, it may be confirmed that plating adhesiveness was poor because partial delamination occurred due to the generation of an alloy phase having a high degree of embrittlement.

The present inventors manufactured Al—Mg alloy plated steel sheets for hot press forming according to the conditions of Inventive Examples 1 and 13, performed salt spray tests on the Al—Mg alloy plated steel sheets and a general Al plated steel sheet plated with Al at a plating weight of 40 g/m² in order to evaluate corrosion resistance, and photographed the foregoing plated sheets, and the results thereof are shown in FIG. 4. In FIG. 4, (a), is a photograph of the general Al plating steel sheet, (b), is a photograph of the Al—Mg alloy plated steel sheet according to Inventive Example 13, and (c) is the Al—Mg alloy plated steel sheet according to Inventive Example 1. It may be confirmed from the foregoing results that while corrosion occurred considerably severe in the general Al plated steel sheet, corrosion resistances were improved in the Al—Mg alloy plated steel sheets according to the present invention because degrees of corrosion were remarkably decreased.

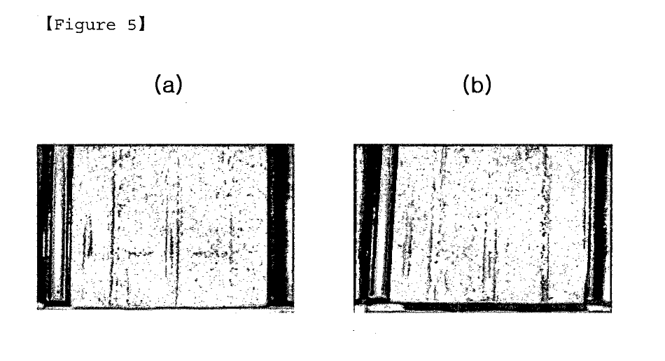

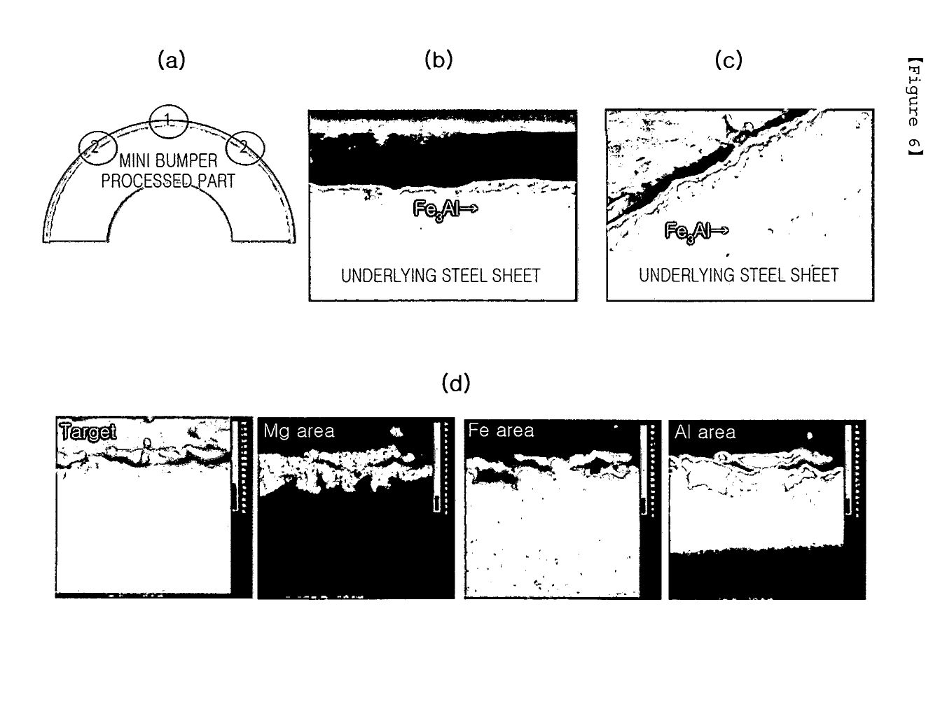

Also, the present inventors actually manufactured mini bumpers by using the general Al plated steel sheet and the Al—Mg alloy plated steel sheet manufactured according to Inventive Example 13. Heating was performed at 950° C. for 10 minutes before hot pressing, and experiments for confirming appearances of surfaces of the steel sheets, presence of the generation of surface scales, and plating adhesiveness were then performed. Photographs related thereto are presented in FIGS. 5 and 6. FIG. 5, (a) shows a mini bumper using the general Al plated steel sheet and (b) shows a mini bumper using the Al—Mg alloy plated steel sheet according to Inventive Example 13. It may be confirmed that surface cracks were generated in (a), while surface appearance was very good and plating adhesiveness was also excellent in (b).

In FIG. 6, SEM micrographs of cross sections of the mini bumper manufactured according to Inventive Example 13 are presented in (b) and (c), while (a) is a schematic diagram illustrating portions of the mini bumper where the SEM photographs were taken. Also, (d) shows a result of electron probe microanalysis (EPMA) element mapping obtained from cross sections of underlying steel sheet and plating layer. According to energy dispersive X-ray (EDX) analysis of the plating layer, micro Vickers hardness, and comprehensive analysis of a phase diagram of Fe—Al, it may be confirmed that cracks were not generated in the plating layer, corrosion resistance of the mini bumper was considerably improved because a thickness share of a relatively ductile (Fe₃Al+FeAl) intermetallic compound layer in a total plating layer was 80%, or more after a hot press forming heat treatment, and a thickness of a Fe₂Al₅ intermetallic compound layer affecting the generation of cracks in the plating layer was decreased.

While the present invention has been shown and described in connection with the exemplary embodiments, it will be apparent to those skilled in the art that modifications and variations can be made without departing from the spirit and scope of the invention as defined by the appended claims.

1. An aluminum (Al) plating layer/aluminum (Al)-magnesium (Mg) plating layer multi-layered structure alloy plated steel sheet having excellent plating adhesiveness and corrosion resistance comprising:
an underlying steel sheet;
an Al plating layer including about 85 wt % or more of Al formed on the underlying steel sheet; and
an Al—Mg plating layer formed on the Al plating layer.

2. The Al plating layer/Al—Mg plating layer multi-layered structure alloy plated steel sheet having excellent plating adhesiveness and corrosion resistance of claim 1, wherein the Al—Mg plating layer comprises about 20 wt % to about 80 wt % of Mg, residual Al and other unavoidable impurities.

3. The Al plating layer/Al—Mg plating layer multi-layered structure alloy plated steel sheet having excellent plating adhesiveness and corrosion resistance of claim 1, wherein a thickness of the Al plating layer is within a range of about 3.5 μm to about 15 μm.

4. The Al plating layer/Al—Mg plating layer multi-layered structure alloy plated steel sheet having excellent plating adhesiveness and corrosion resistance of claim 3, wherein a thickness of the Al—Mg plating layer is within a range of about 1 μm to about 5 μm.

5. A method of manufacturing an Al plating layer/Al—Mg plating layer multi-layered structure alloy plated steel sheet having excellent plating adhesiveness and corrosion resistance, the method comprising:
plating an underlying steel sheet with Al to form an Al plating layer having about 85 wt % or more of Al;
vacuum depositing Mg on the Al plating layer to form a Mg deposition layer; and
performing an alloying heat treatment on a steel sheet including the Al plating layer and the Mg deposition layer in a temperature range of about 350° C. to abut 450° C. for about 3 seconds to about 100 seconds to form an Al—Mg plating layer on the Al plating layer.

6. The method of claim 5, wherein the forming of the Al plating layer is performed such that the Al plating layer has a thickness within a range of about 3.5 μm to about 15 μm.

7. The method of claim 5, wherein the forming of the Mg deposition layer is performed by vacuum depositing Mg at a degree of vacuum range of about 10⁻² mbar to about 10⁻⁵ mbar.

8. The method of claim 5, wherein the forming of the Mg deposition layer is performed such that the Mg deposition layer has a thickness within a range of about 0.3 μm to about 2.0 μm.

9. The Al plating layer/Al—Mg plating layer multi-layered structure alloy plated steel sheet having excellent plating adhesiveness and corrosion resistance of claim 2, wherein a thickness of the Al plating layer is within a range of about 3.5 μm to about 15 μm.

10. The Al plating layer/Al—Mg plating layer multi-layered structure alloy plated steel sheet having excellent plating adhesiveness and corrosion resistance of claim 9, wherein a thickness of the Al—Mg plating layer is within a range of about 1 μm to about 5 μm.

11. The method of claim 6, wherein the forming of the Mg deposition layer is performed such that the Mg deposition layer has a thickness within a range of about 0.3 μm to about 2.0 μm.

12. The method of claim 7, wherein the forming of the Mg deposition layer is performed such that the Mg deposition layer has a thickness within a range of about 0.3 μm to about 2.0 μm.
